(19) United States
(12) Patent Application Publication
(10) Pub. No.: US 2026/0086607 A1
(43) Pub. Date: Mar. 26, 2026

(54) INVERTED INFORMATION HANDLING SYSTEM

(71) Applicant: DELL PRODUCTS L.P., Round Rock, TX (US)

(72) Inventors: Abigail M. Meza, Round Rock, TX (US); Emily Clark, Round Rock, TX (US); Daniel J. Carey, Austin, TX (US); James L. Petivan, III, Austin, TX (US)

(21) Appl. No.: 18/895,607

(22) Filed: Sep. 25, 2024

(51) Int. Cl. G06F 1/16; G06F 1/20; H05K 7/20

(52) U.S. Cl. CPC G06F 1/1656; G06F 1/203; H05K 7/20272; G06F 2200/201

(57) ABSTRACT

An information handling system includes a system board and a cooling apparatus. The system board includes an electronic component. The cooling apparatus is to cool the electronic component with a liquid coolant circulated by a cooling distribution unit. The information handling system defines a dry plane, wherein the system board is located above the dry plane, and the cooling apparatus is located below the dry plane adjacent the system board.

### FIELD OF THE DISCLOSURE

The present disclosure generally relates to information handling systems, and more particularly relates to an information handling system that is inverted.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system may include a system board and a cooling apparatus. The system board may include an electronic component. The cooling apparatus may be to cool the electronic component with a liquid coolant circulated by a cooling distribution unit. The information handling system may define a dry plane. The system board may be located above the dry plane, and the cooling apparatus may be located below the dry plane adjacent the system board.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of computing system according to an embodiment of the present disclosure;

FIG. 2 is a top plan view of a removable bottom plate for an information handling system according to an embodiment of the present disclosure;

FIG. 3 is a top plan view of a removable bottom plate for an information handling system according to another embodiment of the present disclosure;

FIG. 4 is a top plan view of a removable bottom plate for an information handling system according to yet another embodiment of the present disclosure;

FIG. 5 is a top plan view of a removable bottom plate for an information handling system according to yet still another embodiment of the present disclosure;

FIG. 6 is a flow diagram of a method for monitoring liquid coolant in an information handling system according to an embodiment of the present disclosure;

FIG. 7 is a front plan view of an information handling system according to an embodiment of the present disclosure;

FIG. 8 is a front plan view of the information handling system in a full inverted position according to an embodiment of the present disclosure;

FIG. 9 is a front plan view of the information handling system in a partial inverted position according to an embodiment of the present disclosure; and

FIG. 10 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

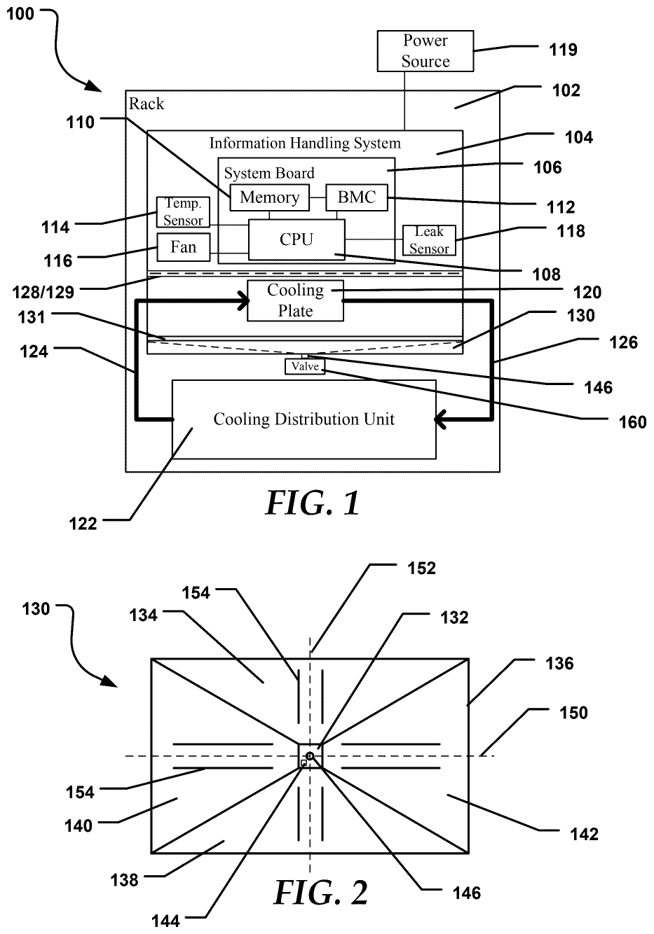

FIG. 1 illustrates a system 100 that may include a rack 102, or cabinet, in which an inverted information handling system 104 is installed, or otherwise disposed. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

As shown, the information handling system 104 may include a system board 106, or motherboard, that may have several electronic components disposed thereon or coupled thereto. For example, the system board 106 may include a central processing unit (CPU) 108 installed, or otherwise disposed, thereon. The information handling system 104 may also include a memory 110 coupled to the CPU 108. Moreover, a baseboard management controller 112 may be disposed on the system board 106 and may be coupled to the CPU 108 and the memory 110. Other components necessary to the operation of the information handling system 104, and well known in the art, may be disposed on the system board 106. The information handling system 104 may also include a temperature sensor 114, a fan 116 adjacent the CPU 108, and an optical leak sensor 118. Additionally, the information handling system 104 may be coupled to a power source 119. The power source 119 may be an alternating current (AC) power source, a direct current (DC) power source, or a combination thereof. The power source 119 may provide power to all of the components described herein that required power to operate.

FIG. 1 further shows a cooling plate 120 adjacent the system board 106. Specifically, the cooling plate 120 is adjacent the CPU 108 which may generate and emit a substantial amount of heat during operation of the information handling system 102. A cooling distribution unit 122 may be connected to the cooling plate 120 via a coolant supply line 124 and a coolant return line 126. It is to be understood that the cooling distribution unit 122 is in fluid communication with the cooling plate 120 via the coolant supply line 124 and the coolant return line 126. During operation, the cooling distribution unit 122 may circulate coolant to the cooling plate 120 via the coolant supply line 124 and the coolant return line 126 in order to lower the temperature of the cooling plate 120 and therefore, transfer heat generated by the CPU 108 away from the CPU 108, and the system board 106, in order to lower the operating temperature of the CPU 108, the system board 106, and the other components disposed on the system board 106.

As shown in FIG. 1, the cooling plate 120 is placed below the system board 106, the CPU 108, and other critical components within the information handling system 104 that are at risk of being damaged in the event of a liquid coolant leak from the cooling plate 120. A dry plane 128 is established within the information handling system 104. As described above, the information handling system 104 is inverted so that the cooling plate 120 is located, or otherwise disposed, below the dry plane 128 while the system board 106 and associated components are located, or otherwise disposed, above the dry plane 128. Specifically, the system board 106 and any electrical components disposed thereon or associated therewith, e.g., the CPU 108, the memory 110, the baseboard management controller 112, the temperature sensor 114, the fan 116, and the optical leak sensor 118, are located above the dry plane 128. Further, any other electrical components that are sensitive to damage from any leaking liquid coolant are also located above the dry plane 128. In the inverted configuration, as shown, the optical leak sensor 118 may be placed, or otherwise position, in a location having a relatively unobstructed line of sight toward a liquid collection area where liquid may pool in case of a leak. In another aspect, described in greater detail below, a conductive leak sensor may be placed in a relatively unobstructed area, e.g., a designated, or predetermined, liquid collection area where liquid may pool due to a leak. It is to be understood that inverting the information handling system 104 may increase the resilience of the information handling system 104, e.g., in the event of a leak.

In the event of a leak, liquid coolant from the cooling plate 120 will remain below the dry plane 128 safely away from the components above the dry plane 128. Moreover, the dry plane 128 may be established by a barrier 129, e.g., a plastic barrier or similar barrier, disposed above the cooling plate 120 to isolate the cooling plate 120 from the components above the barrier 129. In the event of a high pressure leak, the barrier 129 will prevent liquid coolant from spraying above the barrier 129. As further shown in FIG. 1, the information handling system 104 may include a removable bottom plate 130 below the cooling plate 120. The removable bottom plate 130 may include a seal 131 that will render the information handling system 104 substantially liquid tight to prevent any liquid coolant from leaking from the information handling system 104 to any components installed in the rack 102 there below.

Referring to FIG. 2, details of the removable bottom plate 130 are shown. Specifically, the removable bottom plate 130 may include a liquid collection area 132. The liquid collection area 132 may be positioned such that the optical leak sensor 118 is above the liquid collection area 132 and directed toward the liquid collection area 132 to monitor the liquid collection area 132 for the presence of liquid.

A first angled surface 134 may extend from an outer perimeter 136 of the removable bottom plate 130 to the collection area 132. A second angled surface 138, opposite the first angled surface 134, may extend from the outer perimeter 136 to the collection area 132. A third angled surface 140 may extend between the first angled surface 134 and the second angled surface 138 from the outer perimeter 136 to the collection area 132. A fourth angled surface 142 opposite the third angled surface 140 may extend between the first angled surface 134 and the second angled surface 138 from the outer perimeter 136 to the collection area 132. A conductive leak sensor 144 may be placed in the collection area 132 to sense when any liquid coolant is present in the collection 132. A drain 146 may also be disposed, or otherwise installed, in the collection area 132.

As further shown in FIG. 2, the removable bottom plate 130 may define a center X-axis 150 and a center Y-axis 152. One or more stiffening ribs 154 may extend along the first angled surface 134 and the second angled surface 138 parallel to the center Y-axis. Moreover, one or more stiffening ribs may extend along the third angled surface 140 and the fourth angled surface 142 parallel to the center X-axis. One or more angled ribs may be formed in any of the angled surfaces 134, 138, 140, 142. Further, as shown, the angled surfaces 134, 138, 140, 142 extend radially outward around the collection area 132 and in the event of a liquid coolant leak, the angled surfaces 134, 138, 140, 142 will direct the liquid coolant to the collection area 132 for detection by the optical leak sensor 118 or the conductive leak sensor 144.

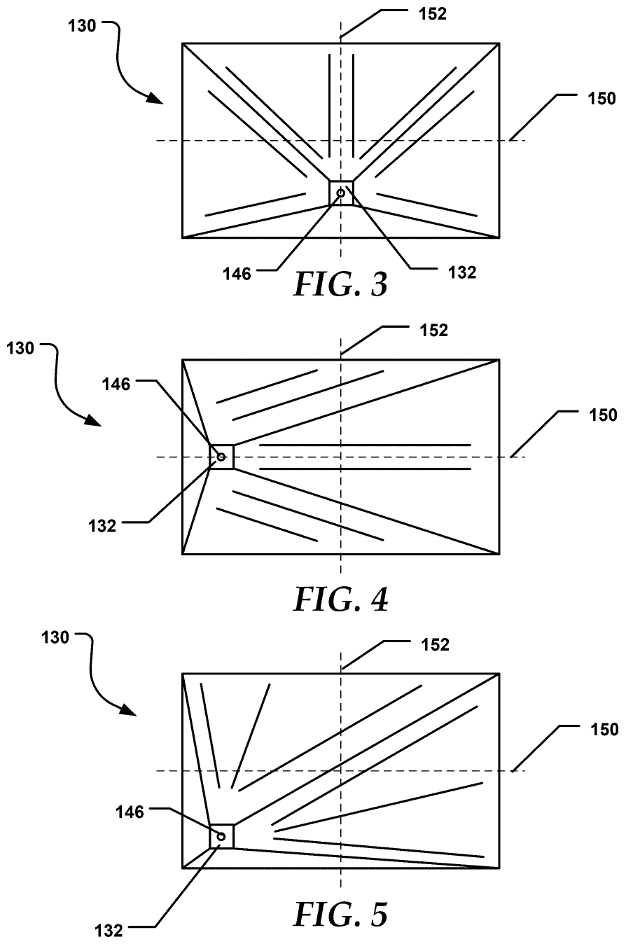

FIG. 2 shows that the collection area 132 and the drain 146 are located along the center X-axis 150 and the center Y-axis 152, i.e., at the intersection thereof at the center of the removable bottom plate 130. However, as shown FIG. 3, the collection area 132 and the drain 146 may be located along the center X-axis 150 and offset from the center Y-axis 152. Further, as illustrated in FIG. 4, the collection area 132 and the drain 146 may be located along the center Y-axis 152 and offset from the center X-axis 154. FIG. 5 shows that the collection area 132 and the drain 146 may be offset from the center X-axis 150 and offset from the center Y-axis 152.

In the event a leak is detected in the information handling system 104, e.g., by the optical leak sensor 118 or the conductive leak sensor 144, an alert may be issued and the information handling system 104 may be de-energized, or powered off. Further, the valve 160 may be opened to release any liquid coolant that has pooled in the collection area 132.

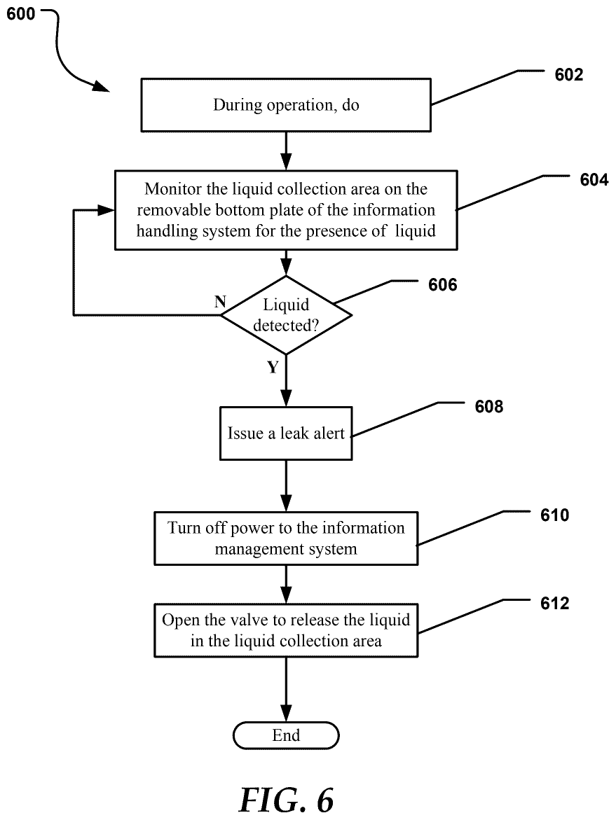

FIG. 6 is a flow diagram of a method 600 for monitoring liquid coolant in an information handling system, e.g., information handling system, according to at least one embodiment of the present disclosure, starting at block 602. It will be readily appreciated that not every method step set forth in this flow diagram is always necessary, and that certain steps of the methods may be combined, performed simultaneously, in a different order, or perhaps omitted, without varying from the scope of the disclosure. The method steps depicted in FIG. 6 may be executed, or employed in whole, or in part, by the baseboard management controller 112, the CPU 108 of the information handling system 104, a combination thereof, or any other type of controller, device, module, processor, or any combination thereof, operable to employ, or otherwise execute, all, or portions of, the method 600 of FIG. 6.

Beginning at block 602, the method 600 may include entering a do loop in which during operation, the following steps are performed. At block 604, the method 600 may include monitoring the liquid collection area 132 on the removable bottom cover 130 of the information handling system 104 for the presence of liquid. The liquid collection area 132 may be monitored using the optical leak sensor 118, the conductive leak sensor 144, or a combination thereof. At decision step 606, the method 600 determines whether a leak is detected. If a leak is not detected, the method 600 returns to block 604 and continues as described herein. On the other hand, at decision step 606, if a leak is detected, the method 600 may proceed to block 608 and may include issuing a leak alert. Thereafter, the method 600 may move to block 610 and the method 600 may include de-energizing, or powering off, the information handling system 610 to prevent overheating. Then, at block 612, the method 600 may include opening the valve 146 to release the liquid in the liquid collection area 132. Thereafter, the method 600 may end.

It can be appreciated that the released liquid coolant may be collected and re-used. Further, a level of the released liquid may be monitored to determine how much liquid coolant has leaked from the cooling plate and the information management system may remain powered on until the level of the leaked and collected liquid coolant reaches a predetermined level indicating that the liquid coolant that continues to circulate through the cooling plate 120 is no longer capable of providing the cooling necessary for proper operation of the information handling system 104. When that level is reached, the information handling system 104 may be powered off.

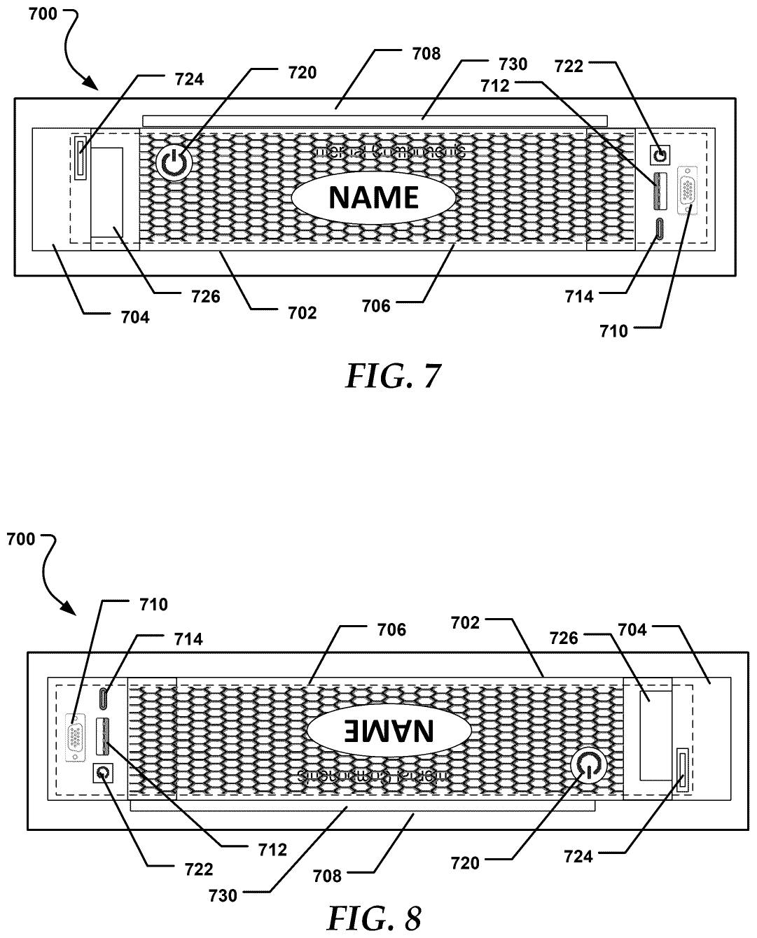

Referring to FIG. 7, an information handling system 700 is illustrated. The information handling system 700 may include a housing 702 having a front bezel 704 and one or more internal electronic components 706 therein. The one or more internal electronic components 706 may include electrical components described above, e.g., the system board 106 and any electrical components disposed thereon or associated therewith, the CPU 108, the memory 110, the baseboard management controller 112, the temperature sensor 114, the fan 116, the optical leak sensor 118, etc. As shown, the information handling system 700 may be installed within a rack 708.

The front bezel 704 may include a first port 710, a second port 712, and a third port 714. For example, the first port 710 may include a video graphics array (VGA) port. The second port 712 may include a universal serial bus 2.0 (USB 2.0) port. Further, the third port 714 may include an Integrated Dell Remote Access Controller (iDRAC) direct micro-AB USB port. It is to be understood that these ports 710, 712, 714 are exemplary and the information handling system 700 may include more ports, and/or different ports, than specified herein.

FIG. 7 shows that the front bezel 704 may further include a first power button 720 and a second power button 722. Further, the front bezel 704 may include a light emitting diode (LED) indicator 724 that may glow when the power to the information handling system 700 is on. The front bezel 704 may also include a release button 726 that may be pressed in order to remove the information handling system 700 from the rack 708. As illustrated, the information handling system 700 may include a cooling plate 730 above the internal electronic components 706 to carry heat away from the internal electronic components 706.

In one aspect, as shown in FIG. 8, to prevent liquid coolant leaks from the cooling plate 730 from damaging the internal electronic components, the entire information handling system 700 may be inverted and installed in the rack 708. In this case, the cooling plate 730 is disposed below the internal electronic components 706 and any liquid coolant that escapes the cooling plate 730 would fall below the cooling plate 730. Further, in this case the rails (not shown) on which the information handling system 700 are may be inverted. In this case, a standard server (i.e., a “right side up” server) may be provided in accordance with the current embodiments by installing the standard server in the server rack in an “upside down” position based upon the rails being inverted. In an alternate case, the rails on the rack may be inverted, permitting the standard server to be mounted in the rack in the “upside down” position. In another aspect, both the rails in the rack and the rails on the information handling system 700 are mounted in the normal position, but the case of the information handling system may be inverted, thereby resulting in the information handling system being in the “upside down” position.

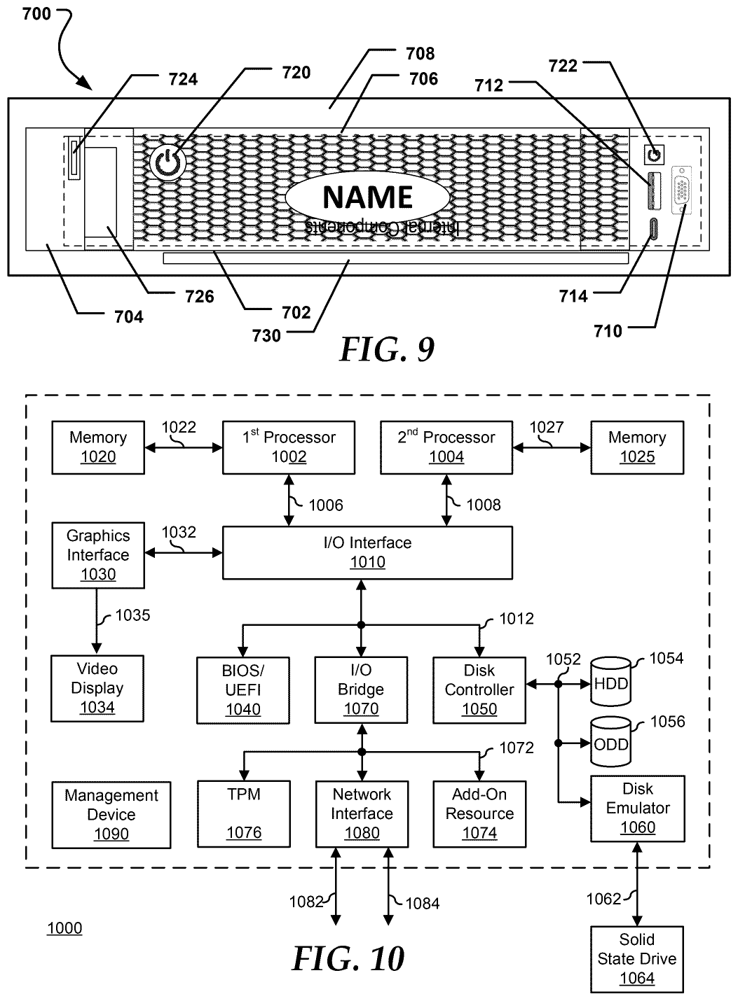

It will be understood that such solutions for providing an inverted server may present additional difficulties, particularly with standard positioning of various components within a server rack. For example, back-of-server components, such as power supplies, I/O modules, or the like, may be most suitably provided on in a particular location to maximize back-of-rack wiring, and the like. As such, in another aspect, illustrated in FIG. 9, the housing 702, the internal components 706, and the cooling plate 730 may be inverted while the front bezel 704 and the components thereon, and other components at the back-fo-rack remain in the upright position initially shown in FIG. 7. In this case, the cooling plate 730 is disposed below the internal electronic components 706 and any liquid coolant that escapes the cooling plate 730 would fall below the cooling plate 730. However, the user interface features provided by the front bezel 704 remain the same.

FIG. 10 shows a generalized embodiment of an information handling system 1000 according to an embodiment of the present disclosure. Information handling system 1000 may be substantially similar to the information handling system 104 of FIG. 1 or the information handling system 204 of FIG. 2. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 1000 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 1000 can include processing resources for executing machine-executable code, such as a central processing unit (CPU), a programmable logic array (PLA), an embedded device such as a System-on-a-Chip (SoC), or other control logic hardware. Information handling system 1000 can also include one or more computer-readable medium for storing machine-executable code, such as software or data. Additional components of information handling system 1000 can include one or more storage devices that can store machine-executable code, one or more communications ports for communicating with external devices, and various input and output (I/O) devices, such as a keyboard, a mouse, and a video display. Information handling system 1000 can also include one or more buses operable to transmit information between the various hardware components.

Information handling system 1000 can include devices or modules that embody one or more of the devices or modules described below and operates to perform one or more of the methods described herein. Information handling system 1000 includes a processors 1002 and 1004, an input/output (I/O) interface 1010, memories 1020 and 1025, a graphics interface 1030, a basic input and output system/universal extensible firmware interface (BIOS/UEFI) module 1040, a disk controller 1050, a hard disk drive (HDD) 1054, an optical disk drive (ODD) 1056, a disk emulator 1060 connected to an external solid state drive (SSD) 1064, an I/O bridge 1070, one or more add-on resources 1074, a trusted platform module (TPM) 1076, a network interface 1080, a management device 1090, and a power supply 1095. Processors 1002 and 1004, I/O interface 1010, memory 1020, graphics interface 1030, BIOS/UEFI module 1040, disk controller 1050, HDD 1054, ODD 1056, disk emulator 1060, SSD 1064, I/O bridge 1070, add-on resources 1074, TPM 1076, and network interface 1080 operate together to provide a host environment of information handling system 1000 that operates to provide the data processing functionality of the information handling system. The host environment operates to execute machine-executable code, including platform BIOS/UEFI code, device firmware, operating system code, applications, programs, and the like, to perform the data processing tasks associated with information handling system 1000.

In the host environment, processor 1002 is connected to I/O interface 1010 via processor interface 1006, and processor 1004 is connected to the I/O interface via processor interface 1008. Memory 1020 is connected to processor 1002 via a memory interface 1022. Memory 1025 is connected to processor 1004 via a memory interface 1027. Graphics interface 1030 is connected to I/O interface 1010 via a graphics interface 1032 and provides a video display output 1036 to a video display 1034. In a particular embodiment, information handling system 1000 includes separate memories that are dedicated to each of processors 1002 and 1004 via separate memory interfaces. An example of memories 1020 and 1025 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 1040, disk controller 1050, and I/O bridge 1070 are connected to I/O interface 1010 via an I/O channel 1012. An example of I/O channel 1012 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 1010 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 1040 includes BIOS/UEFI code operable to detect resources within information handling system 1000, to provide drivers for the resources, initialize the resources, and access the resources. BIOS/UEFI module 1040 includes code that operates to detect resources within information handling system 1000, to provide drivers for the resources, to initialize the resources, and to access the resources.

Disk controller 1050 includes a disk interface 1052 that connects the disk controller to HDD 1054, to ODD 1056, and to disk emulator 1060. An example of disk interface 1052 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 1060 permits SSD 1064 to be connected to information handling system 1000 via an external interface 1062. An example of external interface 1062 includes a USB interface, an IEEE 10394 (Firewire) interface, a proprietary interface, or a combination thereof. Alternatively, solid-state drive 1064 can be disposed within information handling system 1000.

I/O bridge 1070 includes a peripheral interface 1072 that connects the I/O bridge to add-on resource 1074, to TPM 1076, and to network interface 1080. Peripheral interface 1072 can be the same type of interface as I/O channel 1012 or can be a different type of interface. As such, I/O bridge 1070 extends the capacity of I/O channel 1012 when peripheral interface 1072 and the I/O channel are of the same type, and the I/O bridge translates information from a format suitable to the I/O channel to a format suitable to the peripheral channel 1072 when they are of a different type. Add-on resource 1074 can include a data storage system, an additional graphics interface, a network interface card (NIC), a sound/video processing card, another add-on resource, or a combination thereof. Add-on resource 1074 can be on a main circuit board, on separate circuit board or add-in card disposed within information handling system 1000, a device that is external to the information handling system, or a combination thereof.

Network interface 1080 represents a NIC disposed within information handling system 1000, on a main circuit board of the information handling system, integrated onto another component such as I/O interface 1010, in another suitable location, or a combination thereof. Network interface device 1080 includes network channels 1082 and 1084 that provide interfaces to devices that are external to information handling system 1000. In a particular embodiment, network channels 1082 and 1084 are of a different type than peripheral channel 1072 and network interface 1080 translates information from a format suitable to the peripheral channel to a format suitable to external devices. An example of network channels 1082 and 1084 includes InfiniBand channels, Fibre Channel channels, Gigabit Ethernet channels, proprietary channel architectures, or a combination thereof. Network channels 1082 and 1084 can be connected to external network resources (not illustrated). The network resource can include another information handling system, a data storage system, another network, a grid management system, another suitable resource, or a combination thereof.

Management device 1090 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 1000. In particular, management device 1090 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 1000, such as system cooling fans and power supplies. Management device 1090 can include a network connection to an external management system, and the management device can communicate with the management system to report status information for information handling system 1000, to receive BIOS/UEFI or system firmware updates, or to perform other task for managing and controlling the operation of information handling system 1000.

Management device 1090 can operate off of a separate power plane from the components of the host environment so that the management device receives power to manage information handling system 1000 when the information handling system is otherwise shut down. An example of management device 1090 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 1090 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. An information handling system, comprising:
a system board including an electronic component; and
a cooling apparatus to cool the electronic component with a liquid coolant circulated by a cooling distribution unit, wherein the information handling system defines a dry plane, the system board is located above the dry plane, and the cooling apparatus is located below the dry plane adjacent the system board.

1. The information handling system of claim 1, further comprising:
a bottom plate below the cooling apparatus, the bottom plate including a liquid collection area to pool any liquid coolant that leaks from the cooling apparatus.

2. The information handling system of claim 2, further comprising:
a leak sensor to monitor the liquid collection area in the bottom plate for the presence of the liquid coolant.

3. The information handling system of claim 3, further comprising:
a processor to issue a leak alert when the presence of the liquid coolant within the liquid collection area is detected.

4. The information handling system of claim 4, wherein the processor is further to de-energize the information handling system when the leaked is detected.

5. The information handling system of claim 2, wherein the bottom plate further includes at least one angled surface extending from the liquid collection area.

6. The information handling system of claim 6, wherein the bottom plate further includes a drain disposed in the fluid collection area.

7. The information handling system of claim 2, wherein the bottom plate defines a center X-axis and a center Y-axis and the liquid collection area is located along the center X-axis and along the center Y-axis.

8. The information handling system of claim 2, wherein the bottom plate defines a center X-axis and a center Y-axis and the liquid collection area is located along the center X-axis and offset from the center Y-axis.

9. The information handling system of claim 2, wherein the bottom plate defines a center X-axis and a center Y-axis and the liquid collection area is located along the center Y-axis and offset from the center X-axis.

10. The information handling system of claim 2, wherein the bottom plate defines a center X-axis and a center Y-axis and the liquid collection area is offset from the center X-axis and offset from the center Y-axis.

12. A method comprising:
providing, in an information handling system, a system board including an electronic component;
providing, in the information handling system, a cooling apparatus to cool the electronic component with a liquid coolant circulated by a cooling distribution unit; and
defining, in the information handling system, a dry plane, wherein the system board is located above the dry plane, and the cooling apparatus is located below the dry plane adjacent the system board.

13. The method of claim 12, further comprising:
providing, in the information handling system, a bottom plate below the cooling apparatus; and
providing, in the bottom plate, a liquid collection area to pool any liquid coolant that leaks from the cooling apparatus.

14. The method of claim 13, further comprising:
providing, in the liquid collection area, a leak sensor to monitor the bottom plate for the presence of the liquid coolant.

15. The method of claim 14, further comprising:
providing, in the information handling system, a processor to issue a leak alert when the presence of the liquid coolant within the liquid collection area is detected.

16. The method of claim 15, further comprising:
de-energizing, by the processor, the information handling system when the leaked is detected.

17. A system comprising:
a cooling distribution unit; and
an information handling system, including:
a system board having an electric component that emits heat;
a cooling apparatus adjacent the the electric component, the cooling apparatus in fluid communication with the cooling distribution unit, wherein the cooling distribution unit circulates liquid coolant through the cooling apparatus to carry the heat away from the electric component; and
a bottom plate below the cooling apparatus, the bottom plate including a liquid collection area;
wherein the information handling system defines a dry plane, the system board and the electric component is located above the dry plane, and the cooling apparatus is located below the dry plane.

11. The system of claim 17, further comprising:
a leak sensor to monitor the liquid collection area in the bottom plate for the presence of liquid.

12. The system of claim 18, wherein the leak sensor is an optical leak sensor positioned above the liquid collection area.

20. The system of claim 18, wherein the leak sensor is a conductive leak sensor positioned within the liquid collection area.
